(19) United States
(12) Patent Application Publication
(10) Pub. No.: US 2026/0316171 A1
(43) Pub. Date: Oct. 15, 2026

(54) NIPPLE CHUCK

(71) Applicant: Milwaukee Electric Tool Corporation, Brookfield, WI (US)

(72) Inventors: Joseph J. Pechstein, Brookfield, WI (US); Joseph C. Illg, Brookfield, WI (US); John N. Uelmen, Brookfield, WI (US); Matthew R. Wolf, Brookfield, WI (US); Nolan J. Henton, Brookfield, WI (US)

(21) Appl. No.: 19/646,844

(22) Filed: Apr. 14, 2026

Related U.S. Application Data
(60) Provisional application No. 63/788,306, filed on Apr. 14, 2025.
(60) Provisional application No. 63/813,965, filed on May 29, 2025.

(51) Int. Cl. B23G 1/52; B23G 1/22

(52) U.S. Cl. CPC B23G 1/52; B23G 1/22; B23G 2240/12

(57) ABSTRACT

A chuck for a threader tool includes a body having a first end and a second end, a first support assembly at the first end of the body, and a second support assembly at the second end of the body. The first support assembly includes a first support section with a plurality of teeth circumferentially arranged around the first support section and configured to engage an inner surface of a first pipe of a first diameter. The second support assembly includes a second support section with a plurality of teeth circumferentially arranged around the second support section and configured to engage an inner surface of a second pipe of a second, different diameter.

### CROSS-REFERENCE TO RELATED APPLICATIONS

This application claims priority to U.S. Provisional Application No. 63/813,965, filed May 29, 2025, and U.S. Provisional Application No. 63/788,306, filed April 14, 2025, each of which are hereby incorporated by reference in its entirety.

### BACKGROUND

In some construction scenarios, operators may need to manufacture pipe nipples using threader tools. This process typically requires a nipple chuck, which holds the pipe during threading. However, current nipple chucks are generally designed to accommodate only a single pipe size (e.g., diameter), which may pose a challenge for operators who frequently work with pipes of varying dimensions.

### SUMMARY

According to one aspect of the present disclosure, a chuck for a threader tool is provided. The chuck can include a body having a first end and a second end. The chuck can include a first support assembly at the first end of the body, the first support assembly including a first support section with a plurality of teeth circumferentially arranged around the first support section and configured to engage an inner surface of a first pipe of a first diameter. The chuck can include a second support assembly at the second end of the body, the second support assembly including a second support section with a plurality of teeth circumferentially arranged around the second support section and configured to engage an inner surface of a second pipe of a second, different diameter.

In some examples, the first support assembly may further include a third support section, and the third support section may have a different diameter than the first support section.

In some examples, the second support assembly may further include a fourth support section, and the fourth support section may have a different diameter than the second support section.

In some examples, the chuck may further include a first flange arranged between the first support section and the third support section, and a second flange arranged between the first support section and the body.

In some examples, the teeth may be configured to engage the inner surface of the pipe when the pipe is rotated in a first direction, and disengage from the inner surface of the pipe when the pipe is rotated in a second direction opposite the first direction.

In some examples, the chuck may further include a biasing element arranged adjacent the plurality of teeth, the biasing element to bias the teeth into contact with an inner surface of a pipe.

In some examples, each of the plurality of teeth may include a lead-in chamfer configured to guide the pipe along the teeth.

In some examples, the chuck may further include a rotation constraint system including a tab receptacle formed in a first face of the first support section, and a locking tab extending from a first face of the second support section toward the first face of the first support section, the locking tab engaging with the tab receptacle to prevent rotation of the first and second support sections relative to each other.

In some examples, the first support section may include an opening formed at a distal end of the first support section, the opening extending axially through the first support section toward the body.

In some examples, the opening may be configured to permit insertion of a reaming cone through the first support section to ream an interior of a pipe installed on the first support section.

According to another aspect of the present disclosure, a method of securing a pipe for a threading operation is provided. The method can include providing a chuck having a body with first and second support assemblies, each of the first and second support assemblies including a support section of a different diameter. The method can include aligning an end of the pipe with the support section corresponding to a diameter of the pipe. The method can include sliding the pipe over the corresponding support section until an end of the pipe contacts a flange extending from the body. The method can include locking rotation of the chuck and pipe together by rotating the chuck or pipe to cause teeth on the support section to engage an inner surface of the pipe.

In some examples, the first support assembly may include a first support section and a third support section having a different diameter than the first support section.

In some examples, the second support assembly may include a second support section and a fourth support section having a different diameter than the second support section.

In some examples, the method may further include a first flange arranged between the first support section and the third support section, and a second flange arranged between the first support section and the body.

In some examples, the method may further include engaging the teeth with the inner surface of the pipe when the pipe is rotated in a first direction, and disengaging the teeth from the inner surface of the pipe when the pipe is rotated in a second direction opposite the first direction.

According to yet another aspect of the present disclosure, a chuck for a threader tool is provided. The chuck can include a body having a first end and a second end. The chuck can include a first support assembly at the first end of the body, the first support assembly including a first support section and a second support section, with the first support section having a larger diameter than the second support section. The chuck can include a second support assembly at the second end of the body, the second support assembly including a third support section and a fourth support section, with the third support section having a larger diameter than the fourth support section. The chuck can include a plurality of spring-loaded teeth circumferentially arranged on each of the support sections, the teeth configured to engage an inner surface of a pipe.

In some examples, the chuck may further include a rotation constraint system including a tab receptacle formed in a first face of the first support section, and a locking tab extending from a first face of the second support section toward the first face of the first support section, the locking tab engaging with the tab receptacle to prevent rotation of the first and second support sections relative to each other.

In some examples, the rotation constraint system may further include a gusset plate arranged between the first face of the first support section and the first face of the second support section.

In some examples, the gusset plate may include a thru-hole to permit the locking tab to extend through the gusset plate and into the tab receptacle.

In some examples, the chuck may further include a first flange arranged between the first support section and the second support section, and a second flange arranged between the first support section and the body.

### BRIEF DESCRIPTION OF THE DRAWINGS

The accompanying drawings, which are incorporated in and form a part of this specification, illustrate embodiments of the invention and, together with the description, serve to explain the principles of embodiments of the invention:

FIG. 1 is a diagrammatic view of a threader tool including a nipple chuck according to aspects of the present disclosure.

FIG. 2 is an axonometric view of the nipple chuck of FIG. 1.

FIG. 3 is a cross-sectional view of the nipple chuck of FIG. 2, taken along III-III.

FIG. 4 is a front view of the nipple chuck of FIG. 1.

FIG. 5 is a side view of a pipe engaged with the nipple chuck of FIG. 1.

FIG. 6 is an axonometric view of another example of a nipple chuck for use with the threader tool of FIG. 1.

FIG. 7 is a side view of another example of a nipple chuck for use with the threader tool of FIG. 1.

FIG. 8 is an exploded view of a rotation constraint system of the nipple chuck of FIG. 1.

FIG. 9 is an axonometric view of another example of a nipple chuck for use with the threader tool of FIG. 1.

FIG. 10 is a cross-sectional view of the nipple chuck of FIG. 9.

FIG. 11 is cross-sectional view of the nipple chuck of FIG. 9 with a pipe engaged with the nipple chuck and a reaming cone in use.

FIG. 12 is a cross-sectional view of the nipple chuck of FIG. 9 depicting a double-D shaped locking mechanism.

### DETAILED DESCRIPTION

The following discussion is presented to enable a person skilled in the art to make and use embodiments of the invention. Given the benefit of this disclosure, various modifications to the illustrated embodiments will be readily apparent to those skilled in the art, and the principles herein can be applied to other embodiments and applications without departing from embodiments of the invention. Thus, embodiments of the invention are not intended to be limited to embodiments shown, but are to be accorded the widest scope consistent with the principles and features disclosed herein.

As generally noted above, current nipple chucks are designed to work with a single pipe diameter, which may pose a challenge for operators who frequently work with pipes of varying diameters. For example, to work with pipes of varying diameters, the operator may have to constantly insert and remove nipple chucks of varying sizes.

To mitigate these issues, the operator may instead utilize a nipple chuck having a pair of support assemblies arranged on opposing ends of a body of the chuck. In some examples, the support assemblies may include one or more support sections (e.g., cylindrical sections of different diameters) configured to engage pipes of different diameters. Thus, the chuck may accommodate pipes of multiple diameters without needing replacement. In some examples, the chuck may further include one or more radially extending flanges separating the different support sections of the support assemblies. In some examples, the flanges may serve as end stops to facilitate proper pipe positioning on the respective support sections.

In some examples, the support sections may include one or more spring-loaded teeth arranged circumferentially around an exterior of the support sections. In some examples, The teeth may be configured to engage an interior surface of the pipe when the chuck or pipe is rotated in a first direction (e.g., during a threading operation) and disengage from the interior surface of the pipe when rotated in a second, opposite direction (e.g., to facilitate pipe removal).

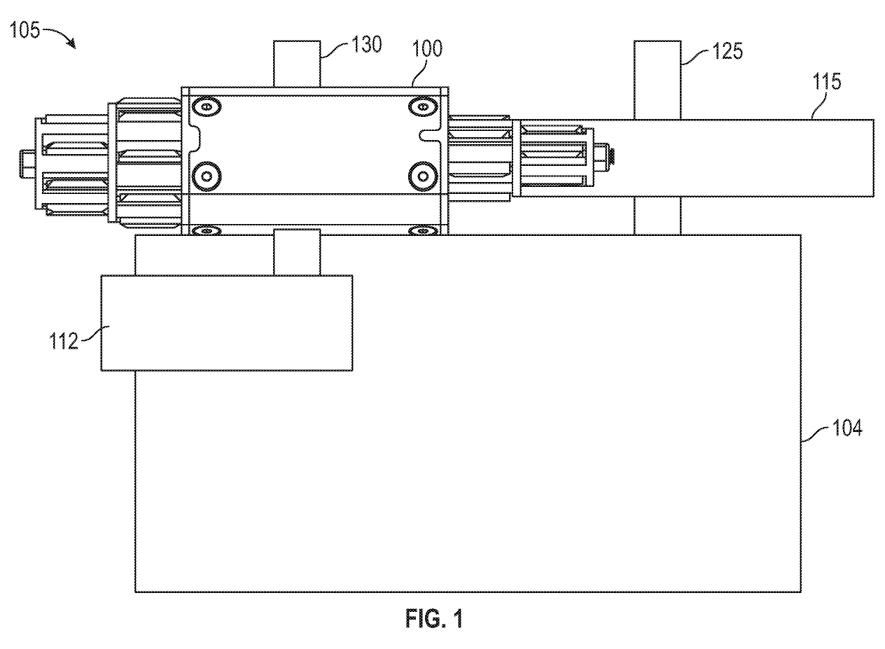

FIG. 1 illustrates an example of a threader tool 105, which may be used to cut or otherwise form threads in a piece of pipe 115 (e.g., to create pipe nipples, threaded connections, etc.). In some examples, the pipe 115 may be formed from metal, such as steel, iron, or copper, or from other suitable materials. The threader tool 105 may be a portable unit, a benchtop unit, or another suitable configuration. In some examples, the threader tool 105 may be powered electrically, pneumatically, hydraulically, or by other suitable means.

The threader tool 105 may include a frame 104, which may provide structural support for the various components of the threader tool 105. For instance, the frame 104 may include portability features, such as handles, wheels, or the like. The threader tool 105 may further include a cutting head 125, a chuck 100 (e.g., a nipple chuck), a drive mechanism 112, a retention system 130, a lubricant system, and a control system.

The cutting head 125 may include one or more cutting dies, which may be used to create (e.g., cut) threads into the pipe 115. In some examples, the cutting dies may be adjustable, replaceable, or configured for different thread types (e.g., NPT, BSPT, etc.) or thread pitches. Further, the chuck 100 may be configured to engage with an interior surface of the pipe 115 in order to secure the pipe 115 during a threading operation (e.g., to mitigate rotation or axial movement of the pipe 115 relative to the chuck 100). Engagement with the interior surface may be achieved via teeth, gripping elements, friction surfaces, or other suitable mechanisms. The chuck 100 may also be configured to accommodate pipes of multiple diameters, without needing to swap or otherwise remove the chuck 100.

In some examples, the retention system 130 (e.g., a three-jaw chuck, a collet, a clamp, or other gripping mechanism) may be configured to receive and retain the chuck 100 so that the drive mechanism 112 (e.g., a gearbox, motor, battery, etc.) can rotate the retention system 130, the chuck 100, and the pipe 115 (e.g., connected to the chuck 100) as a single unit. In some examples, the drive mechanism 112 may be variable speed, reversible, or include torque control features. Additionally, the drive mechanism 112 may rotate the retention system 130, the chuck 100, and the pipe 115 with respect to a fixed cutting head 125 in order to cut threads into the pipe 115. In some examples, the rotation, speed, or direction may be adjustable based on pipe material, diameter, or thread type. Further, the lubrication system may include an oil reservoir and pump that supply lubricating oil to reduce friction and heat during the threading operation. In some examples, the lubricating oil may be delivered via drip, spray, or flood application, and may be recirculated or filtered. Additionally, the control system may include one or more controllers (e.g., each including a processor and a memory), which may control operation of the threader tool 105. In some examples, the control system may also include user inputs (e.g., switches, buttons, touchscreens), indicators (e.g., LEDs, displays), or safety features (e.g., emergency stop, overload protection).

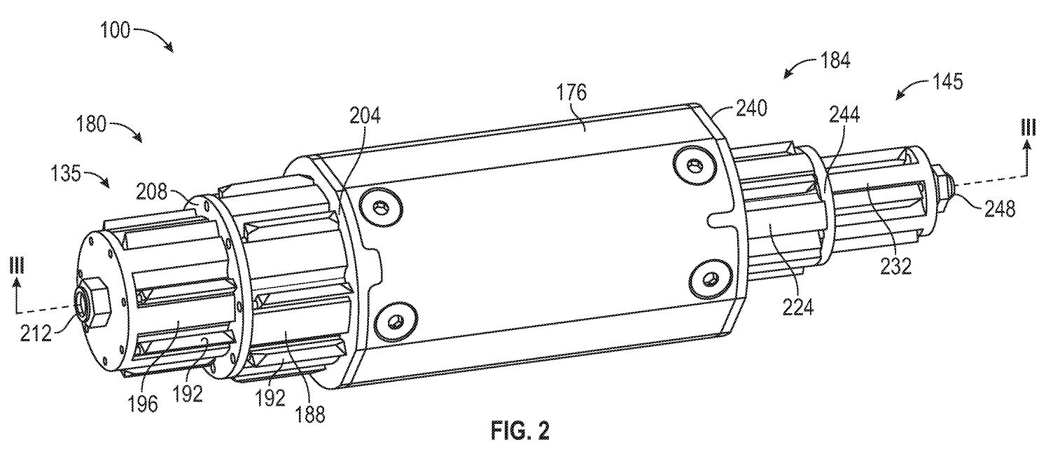

As illustrated in FIGS. 2-4, the chuck 100 may include a substantially cylindrical body 176 with a first support assembly 135 at a first end 180 and a second support assembly 145 at a second, opposite end 184. In some examples, the body 176 may be formed from metal (e.g., steel, aluminum), plastic, or other materials. The body 176 may also be substantially cylindrical in shape and include one or more flat portions (e.g., flat sides) to facilitate gripping of the chuck 100 by the retention system 130 (e.g., a three-jaw-type chuck). The flat portions may include two, three, four, or more flat sides, which may be evenly spaced around the circumference of the body 176, although other configurations are possible. Alternatively, the body 176 may have other cross-sectional shapes, such as hexagonal, square, or polygonal, to facilitate gripping. Furthermore, the body 176 may have a length sufficient to provide clearance between the support assemblies, or the length of the body 176 may be selected based on intended pipe lengths. In some examples, the first and second support assemblies may be substantially cylindrical in shape. In some examples, the first and second support assemblies may be integrally formed with the body 176 or removably attached to the body 176. In one particular example, the first and second support assemblies may each include one or more respective cylindrical (e.g., having a substantially circular cross-section) support sections corresponding to different diameters of pipe.

To restrict movement of the pipe 115 during a threading operation (e.g., rotation of the pipe 115 with respect to the chuck 100), the chuck 100 may include teeth 192 that circumferentially extend from the first support assembly 135 and the second support assembly 145. In some examples, the teeth 192 may be formed from hardened metal, carbide, or other wear-resistant materials. Furthermore, the teeth 192 may have a serrated, knurled, or angled profile to facilitate engagement with the pipe interior. Each support section may include a plurality of teeth (e.g., four, six, eight, or more teeth) evenly spaced around the circumference, which may be configured to engage an inner surface of the pipe 115. For example, rotation of either the chuck 100 or the pipe 115 may cause the teeth 192 to engage the inner surface of the pipe 115, which may lock rotation of the chuck 100 and the pipe 115 together. In some examples, the engagement between the teeth 192 and the pipe interior may provide frictional or mechanical grip to resist torque applied during the threading operation. Additionally, the teeth 192 may resist axial movement of the pipe 115 relative to the chuck 100.

The first support assembly 135 of the chuck 100 may include one or more support sections, with each section having a different diameter (e.g., configured to receive a particular diameter of pipe). For example, the first support assembly 135 may include both a first support section 188 of a first diameter and a second support section 196 having a second, different diameter. In some examples, the support sections may be formed from the same or different materials as the body 176 (e.g., metal, hardened steel, etc.). Additionally, the support sections may be integrally formed with each other or separately formed and assembled together. In some examples, the first support section 188 may have a larger diameter than the second support section 196. Furthermore, the second support section 196 may be arranged further from the body 176 than the first support section 188. Put differently, the first support section 188 may be arranged (e.g., sandwiched) between the body 176 and the second support section 196. In some examples, the transition between the first support section 188 and the second support section 196 may be stepped, tapered, or otherwise configured. Additionally, as mentioned above, the second support section 196 may be configured to engage a pipe with a smaller inner diameter than the first support section 188. In some examples, the support sections may accommodate standard pipe sizes or diameter ranges (e.g., from about 0.5 inches to about 4 inches). Each support section may also have an axial length sufficient to engage a predetermined length of the pipe interior. As noted above, both the first support section 188 and the second support section 196 may include teeth 192 arranged circumferentially around an exterior surface (e.g., circumference) of the first and second support sections 188, 196.

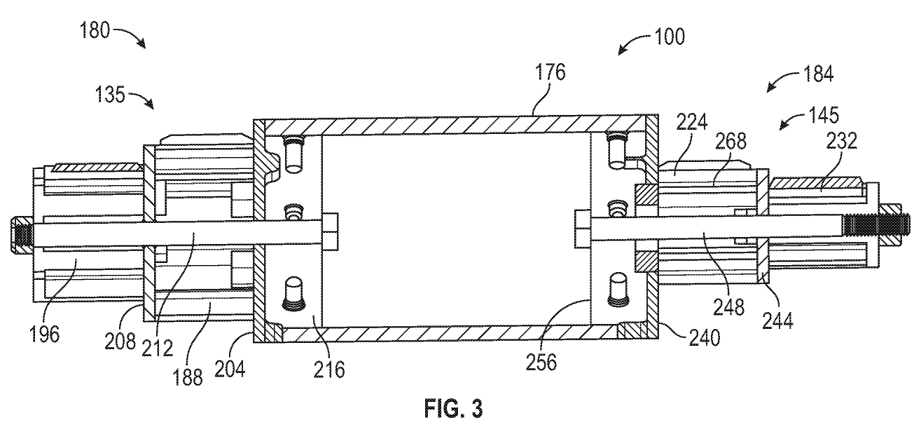

To assist in positioning and alignment of the pipe 115 on the chuck 100, a first flange 208 may be formed between the first and second support sections 188, 196. Correspondingly, a second flange 204 may be formed between the first support section 188 and the body 176. In some examples, the flanges may be integrally formed with the support sections or separately formed and attached. Furthermore, the flanges may be annular, disc-shaped, or have other suitable configurations, and may have a radial thickness or axial width selected for durability or pipe engagement. In some examples, the flanges may be formed from the same or different materials as the support sections. Thus, the arrangement of the first support section 188, the first flange 208, the second support section 196, the second flange 204, and the body 176 may form a stepped profile (see, e.g., FIG. 3) with the diameter increasing from the second support section 196 to the body 176. In some examples, the stepped profile may facilitate visual identification of the correct support section for a given pipe diameter. In some cases, the flanges may include surface features such as markings, textures, or chamfers to assist with pipe alignment or identification.

The first and second flanges 204, 208 may also serve as an end stop for the pipe 115. For example, the pipe may be inserted onto the chuck 100 until contacting the respective flange 204, 208, which may correspond to a particular thread location on the pipe. In some examples, the particular thread location may correspond to a standard thread engagement length or a predetermined distance from the pipe end. In some examples, the end stop may facilitate consistent and repeatable pipe positioning, which may improve threading accuracy or uniformity. Additionally, the first flange 208 may have a diameter greater than that of the first support section 188. Further, the second flange 204 may have a diameter greater than that of the second support section 196. In some examples, the flange diameter may be sized to contact an end face of the pipe without interfering with the pipe interior. Furthermore, the flange may include a contact surface (e.g., flat, angled, or chamfered) configured to abut the pipe end. In some examples, the flange may have a height or thickness sufficient to withstand axial forces applied during the threading operation.

With continued reference to FIGS. 2-4, the second support assembly 145 of the chuck 100, similar to the first support assembly 135, may include one or more support sections, with each section having a different diameter (e.g., a different diameter from both each other and the support sections of the first support assembly). The second support assembly 145 may be substantially similar to or different from the first support assembly 135 in terms of configuration, dimensions, or materials. For instance, the second support assembly 145 may include a third support section 224 having a different diameter from a fourth support section 232. In particular, the third support section 224 may have a larger diameter than the fourth support section 232. The fourth support section 232 may be arranged further from the body 176 than the third support section 224. Put differently, the third support section 224 may be arranged (e.g., sandwiched) between the body 176 and the fourth support section 232. The fourth support section 232 may be configured to engage a pipe with a smaller inner diameter than the third support section 224. In this example, the third and fourth support sections 224, 232 may accommodate standard pipe sizes or diameter ranges (e.g., from about 0.25 inches to about 1.5 inches). Further, both the third and fourth support sections 224, 232 may have a smaller diameter than the first and second support sections 188, 196. Having smaller diameter support sections on the second support assembly 145 may allow the chuck 100 to accommodate a wider range of pipe sizes overall. In some examples, the first and second support assemblies 135, 145 may be interchangeable or may have mirrored configurations. Additionally, both the third support section 224 and the fourth support section 232 may include teeth 192 arranged circumferentially around an exterior surface (e.g., circumference) of the third and fourth support sections 224, 232.

To assist in positioning and alignment of the pipe 115 on the chuck 100, a third flange 244 may be formed between the third and fourth support sections. Correspondingly, a fourth flange 240 may be formed between the third support section 224 and the body 176. In some examples, the flanges may be integrally formed with the support sections or separately formed and attached. Furthermore, the flanges may be annular, disc-shaped, or have other suitable configurations, and may have a radial thickness or axial width selected for durability or pipe engagement. Additionally, the flanges may be formed from the same or different materials as the support sections. Thus, the arrangement of the third support section 224, the third flange 244, the fourth support section 232, the fourth flange 240, and the body 176 may form a stepped profile (see, e.g., FIG. 3) with the diameter increasing from the fourth support section 232 to the body 176. The stepped profile may facilitate visual identification of the correct support section for a given pipe diameter. In some examples, the flanges may include surface features such as markings, textures, or chamfers to assist with pipe alignment or identification.

Additionally, the third and fourth flanges 240, 244 may serve as an end stop for the pipe 115. For example, the pipe may be inserted onto the chuck 100 until contacting the respective flange 240, 244, which may correspond to a particular thread location on the pipe. As noted above, the particular thread location may correspond to a standard thread engagement length or a predetermined distance from the pipe end. In some cases, the end stop may ensure consistent and repeatable pipe positioning. In this example, the third flange 244 may have a diameter greater than that of the third support section 224. Further, the fourth flange 240 may have a diameter greater than that of the fourth support section 232. In some examples, the flange diameter may be sized to contact an end face of the pipe without interfering with the pipe interior. Additionally, the flange may include a contact surface (e.g., flat, angled, or chamfered) configured to abut the pipe end. Furthermore, the flange may have a height or thickness sufficient to withstand axial forces applied during the threading operation.

To secure the first support assembly 135 to the body 176, a fastener 212 (e.g., a bolt, nut, screw, nail, rivet, etc.) may extend through the first support assembly 135 (e.g., including the first and second support sections) and into the body 176. In some examples, the fastener 212 may engage with a threaded bore, a nut, or other retention feature in the body 176. Correspondingly, to secure the second support assembly 145 to the body 176, a fastener 248 (e.g., a bolt, nut, screw, nail, rivet, etc.) may extend through the second support assembly 145 (e.g., including the third and fourth support sections) and into the body 176. In some examples, the fastener 212, 248 may be removable using standard tools (e.g., a wrench, screwdriver, hex key, etc.) or may be tool-free (e.g., a thumbscrew or quick-release mechanism). In some cases, the first and second support assemblies may be replaceable by an operator (e.g., if an operator desires a different diameter of support sections, etc.). This replaceability may allow the operator to customize the chuck 100 for specific applications or replace worn components. The support assemblies may also include alignment features (e.g., keyed surfaces, pins, or indexing marks) to ensure proper orientation during installation. For instance, to replace the first support assembly 135, an operator may remove the fastener 212 and then remove and replace the corresponding support sections. Following this, the operator may reinsert the fastener 212.

Further, the body 176 may include a pair of removable endcaps 216, 256 arranged on either end of the body (e.g., with the endcap 216 arranged between the first support section 188 and the body 176 and the endcap 256 arranged between the third support section 224 and the body 176). In some examples, the endcaps 216, 256 may be formed from metal, plastic, or other suitable materials. In some aspects, the endcaps 216, 256 may be press-fit, threaded, snap-fit, or otherwise secured to the body 176. In this example, the endcaps 216, 256 may be configured to receive and retain a portion of the respective fasteners 212, 248. Accordingly, the endcaps 216, 256 may provide a bearing surface, protect internal components, or distribute loads from the fasteners 212, 248. In some examples, the endcaps 216, 256 may be removable for maintenance, inspection, or replacement of internal components. Furthermore, the endcaps 216, 256 may be disc-shaped, annular, or have other suitable configurations.

As mentioned previously, each of the respective support sections 188, 196, 224, 232 may include a series of circumferentially arranged teeth. For example, the first support section 188 may include a first set of teeth, the second support section 196 may include a second set of teeth, the third support section 224 may include a third set of teeth, and the fourth support section 232 may include a fourth set of teeth. In some examples, the sets of teeth on different support sections may have the same or different configurations (e.g., number of teeth, tooth profile, or tooth material). Furthermore, the teeth may be configured to engage with an interior surface of a pipe in order to lock rotation of the pipe and the chuck (e.g., to mitigate rotation of the pipe during a threading operation). In order to facilitate contact between the teeth and the interior of the pipe, the teeth may be spring-loaded. For example, a biasing element 268 (e.g., a spring, an elastomeric element, compressible foam, or other suitable biasing mechanism) may be arranged underneath each tooth of the set of teeth and configured to bias the teeth outward (e.g., radially outward). In some examples, the biasing element may be arranged in a pocket, groove, or recess formed in the support section. Additionally, the biasing force may be selected to provide sufficient grip while still allowing insertion and removal of the pipe. In some examples, the spring-loaded teeth may accommodate variations in pipe diameter, wall thickness, or surface irregularities.

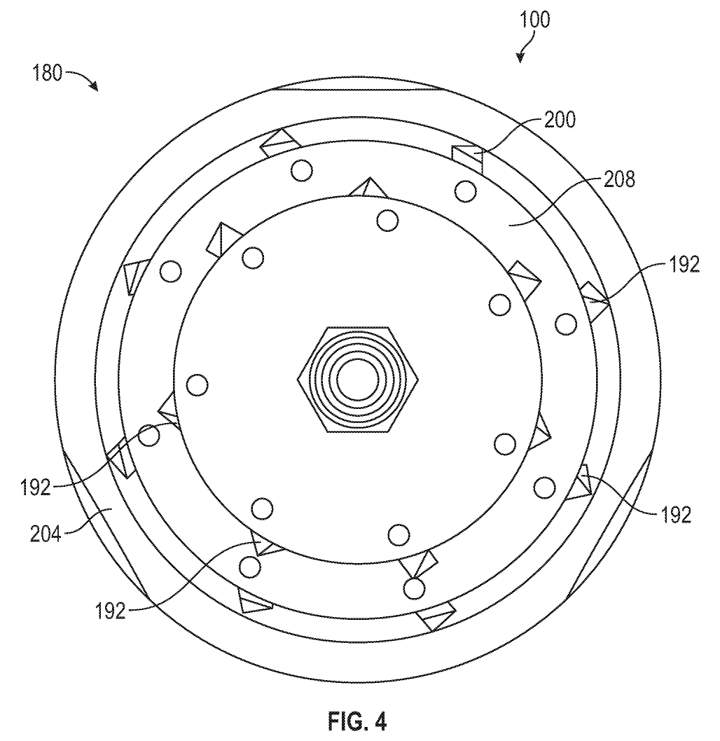

Further, in order to permit insertion of the pipe 115 onto the respective support section, the teeth 192 may each include a lead-in chamfer 200 (see, e.g., FIG. 4), which may guide the pipe along the teeth and correspondingly force the teeth inwards (e.g., against the biasing force provided by the biasing elements 268) as the pipe is inserted on the respective support section. The lead-in chamfer 200 may have an angle (e.g., between about 15 degrees and about 45 degrees) or may be rounded, tapered, or beveled. Furthermore, the lead-in chamfer 200 may be formed at an outer end or tip of each tooth. In some examples, the chamfer may reduce the insertion force required to install the pipe onto the support section. For instance, as the pipe 115 is installed on the chuck 100, the teeth may be compressed (e.g., against the force of the biasing element). Once the pipe is arranged on the chuck 100 (e.g., on the desired support section matching the diameter of the pipe), the teeth may expand (e.g., due to the biasing force of the biasing element) to account for variations in pipe diameter or other pipe deformities (e.g., ovality, dents, or surface irregularities).

The teeth 192 may also be configured to engage the interior surface of the pipe 115 when rotated in a first direction (e.g., clockwise) and disengage from the interior surface of the pipe when rotated in a second, opposite direction (e.g., counterclockwise). In some examples, the directional engagement may be achieved via angled or ramped tooth profiles, one-way clutch features, or other suitable mechanisms. The directional engagement may facilitate removal of the pipe after the threading operation while maintaining secure grip during threading. Further, as mentioned previously, the diameters of each of the support sections may be different to accommodate pipes of different diameters. Additionally, the support section diameters may include tolerances to accommodate variations in pipe manufacturing. For example, a diameter of the first support section 188 may be about 2 inches, a diameter of the second support section 196 may be about 1.5 inches, a diameter of the third support section 224 may be about 1.25 inches, and a diameter of the fourth support section 232 may be about 1 inch. In other examples, the diameters of the support sections may be different. For example, the range of diameters may be from about 4 inches to about .5 inches.

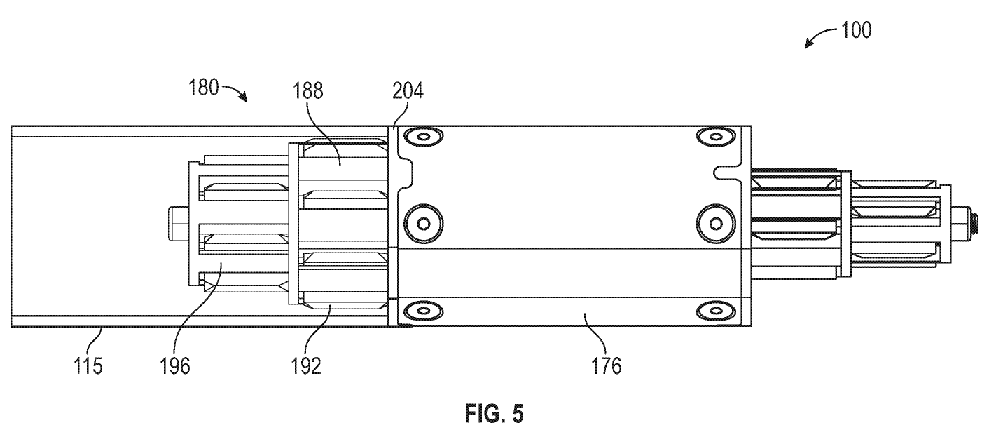

As shown in FIG. 5, to install the pipe 115 onto the chuck 100 an operator may align the end of the pipe with the first or second support assembly 135, 145. As noted above, in some cases, the operator may visually or tactilely identify the correct support section based on the stepped profile, markings, or other indicators. Following this, the operator may slide the pipe over the corresponding first or second support assembly 135, 145 until an end of the pipe contacts the corresponding flange (e.g., end stop). The pipe may then be inserted axially along a longitudinal axis of the chuck. For example, the operator may align the pipe with the support assembly having a support section matching a diameter of the pipe. The operator may confirm proper seating of the pipe by verifying contact with the flange or by observing engagement of the teeth. Once the pipe is arranged on the desired support section the operator may begin the threading operation. The operator may initiate the threading operation via the control system, a switch, or other user input. During the threading operation, the teeth 192 engage the inner surface of the pipe 115 to mitigate the risk of movement of the pipe during the threading operation. As mentioned above, the chuck 100 can be used on different pipes of varying diameters without having to replace the chuck 100, which may reduce the overall number components and increase overall efficiency. This may result in reduced downtime, fewer tool changes, or simplified inventory management.

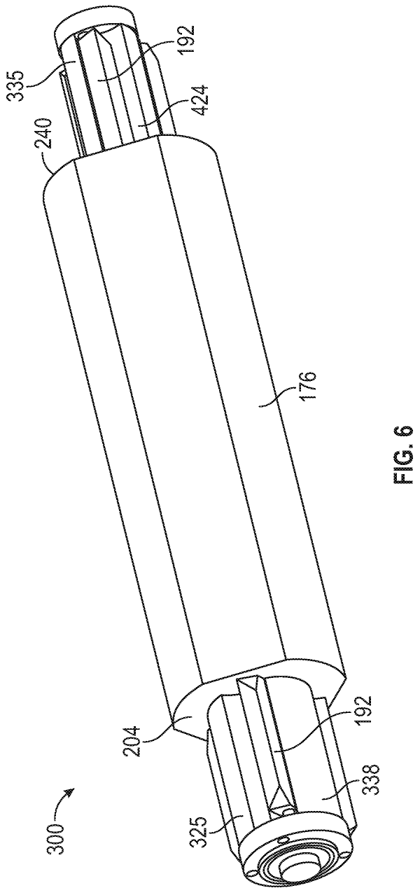

FIG. 6 illustrates another example of a chuck 300. As will be recognized, the chuck 300 shares a number of components in common with and operates in a similar fashion to the examples illustrated and described previously (e.g., the chuck 100). For the sake of brevity, these common features will not be again described below in detail. Rather, previous discussion of commonly named or numbered features, unless otherwise indicated, also applies to example configurations of the chuck 300.

Rather than including a pair of support sections per each support assembly, the chuck 300 may instead include a single support section per each support assembly. The single support section per assembly may simplify manufacturing, reduce cost, or provide a more compact chuck design. Thus, instead of being usable with four different diameters of pipe, the chuck 300 may instead be used with two different diameters of pipe (e.g., one per each support assembly including a single support section of a particular diameter). The chuck 300 may be suitable for operators who primarily work with a limited range of pipe sizes or for specialized applications. With a single support section, a single flange may serve as the end stop for each support assembly. The chuck 300 may also be interchangeable with the chuck 100 in the retention system 130 of the threader tool 105. In this example, a first support assembly 338 may include a first support section 325 for use with a pipe having an inner diameter of between about 0.25 inches and about 2 inches, or between about 0.5 inches and between about 1 inch, or about 0.75 inches. Correspondingly, the second support assembly 424 may include a second support section 335 for use with a pipe having an inner diameter of between about 0.25 inches or about 2 inches, or between about 0.5 inches and about 1 inch, or about 0.5 inches.

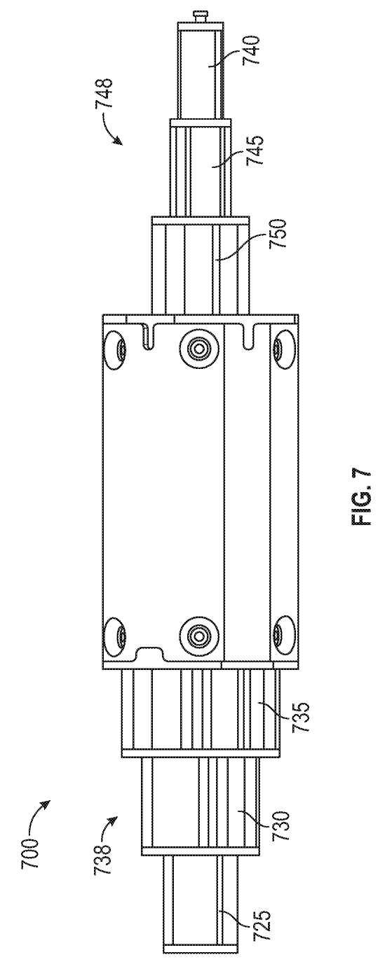

FIG. 7 illustrates another example of a chuck 700. As will be recognized, the chuck 700 shares a number of components in common with and operates in a similar fashion to the examples illustrated and described previously (e.g., the chucks 100, 300). For the sake of brevity, these common features will not be again described below in detail. Rather, previous discussion of commonly named or numbered features, unless otherwise indicated, also applies to example configurations of the chuck 700.

Rather than including a pair of support sections per each support assembly, the chuck 700 may instead include more than a pair of support sections per each support assembly (e.g., three, four, five, or more support sections). Having more than a pair of support sections per assembly may increase versatility, reduce the need for multiple chucks, or allow the operator to handle a wider variety of pipe sizes with a single tool. Thus, instead of being usable with two or four different diameters of pipe, the chuck 700 may instead be used with four (or more) different diameters of pipe (e.g., one per each support assembly including a single support section of a particular diameter). With additional support sections, additional flanges may be arranged between adjacent support sections to serve as end stops. The additional support sections may form an extended stepped profile with progressively increasing diameters. Additional support sections may increase the overall length or complexity of the support assembly.

In particular, a first support assembly 738 may include a first support section 725 for use with a pipe having a first inner diameter, a second support section 730 for use with a pipe having a second inner diameter, and a third support section 735 for use with a pipe having a third inner diameter. Correspondingly, a second support assembly 748 may include a fourth support section 740 for use with a pipe having a fourth inner diameter, a fifth support section 745 for use with a pipe having a fifth inner diameter, and a sixth support section 750 for use with a pipe having a sixth inner diameter. In this example, the support sections may be arranged in order of decreasing diameter from the body outward, although other configurations are possible. Flanges may be arranged between adjacent support sections to serve as end stops for each pipe diameter, as similarly discussed above. In this example, the diameters of the support sections may range from about 0.5 inches to about 4 inches. As should be appreciated, the first and second support assemblies 738, 748 may include different numbers of support sections. For example, the first support assembly 738 may include two support sections, while the second support assembly 748 may include a different number of support sections (e.g., three support sections, etc.).

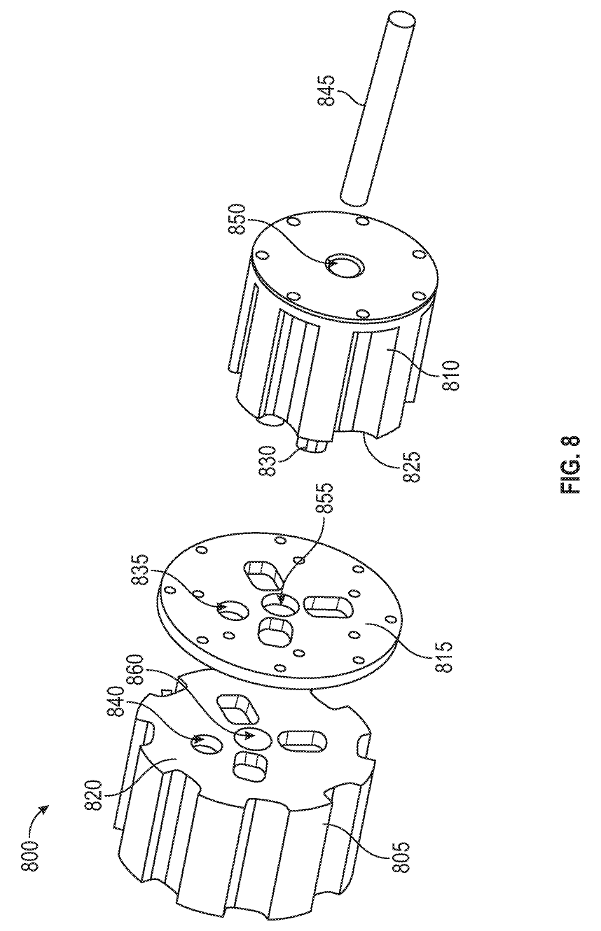

FIG. 8 shows an example of a rotation constraint system 800 for use with the chucks 100, 300, 700 described previously. In some examples, the rotation constraint system 800 may be utilized to mitigate rotation between adjacent support sections (e.g., support sections 745, 750, etc.) of the support assemblies (e.g., support assemblies 738, 748, etc.) during rotation of the chuck (e.g., during a threading operation, etc.). Mitigating rotation between adjacent support sections may provide consistent torque transfer, mitigate loosening of components, or maintain alignment during operation. The rotation constraint system 800 may be particularly beneficial when the support sections are separately formed and assembled together rather than integrally formed. The rotation constraint system 800 may be arranged between any pair of adjacent support sections within a support assembly. Rotation constraint may alternatively be achieved via splines, keyways, interference fits, or other suitable mechanisms.

The rotation constraint system 800 may include a gusset plate 815, which may be arranged between a first support section 805 and a second support section 810 of a support assembly (e.g., of the chuck). In some examples, the gusset plate 815 may be formed from metal, plastic, or other suitable materials. Additionally, the gusset plate 815 may be disc-shaped, annular, or have other suitable configurations, and may have a thickness selected for strength or durability. The gusset plate 815 may be sandwiched between a first face 820 of the first support section 805 and a first face 825 of the second support section 810. Further, to mitigate rotation of the first support section relative to the second support section, the second support section 810 may include one or more locking tabs 830 projecting from the first face 825. In some examples, the locking tabs 830 may be cylindrical, rectangular, or have other suitable cross-sectional shapes. Additionally, the rotation constraint system 800 may include two, three, four, or more locking tabs evenly spaced around the circumference. In this example, the locking tabs 830 may be arranged through one or more corresponding thru-holes in the gusset plate 835 and into one or more tab receptacles 840 (e.g., blind holes) in the first face 820 of the first support section 805. In some examples, the tab receptacles 840 may have a depth sufficient to securely receive the locking tabs 830.

To secure the first support section, the gusset plate, and the second support section together, a fastener 845 (e.g., a bolt, screw, threaded rod, etc.) may be arranged though openings 850, 855, 860 in the first support section, the gusset plate, and the second support section, which may clamp the gusset plate 815 between the first and second support sections 805, 810. In particular, the openings 850, 855, 860 in the first support section, the gusset plate, and the second support section may be axially aligned to receive the fastener 845. Furthermore, the clamping force provided by the fastener 845 may be sufficient to maintain engagement between the locking tabs 830 and tab receptacles 840 during operation. For example, in use, the locking tabs 830 may engage with the tab receptacles 840 in order to resist rotational movement of the first and second support sections relative to each other (e.g., about an axis formed by the fastener 845). As should be appreciated, the rotation constraint system 800 may be used between any adjacent support sections on the chuck as described previously. Further, in some examples, the rotation constraint system may not include the gusset plate. Instead, the locking tabs 830 may directly engage the tab receptacles 840 with the first face of the first support section contacting the first face of the second support section.

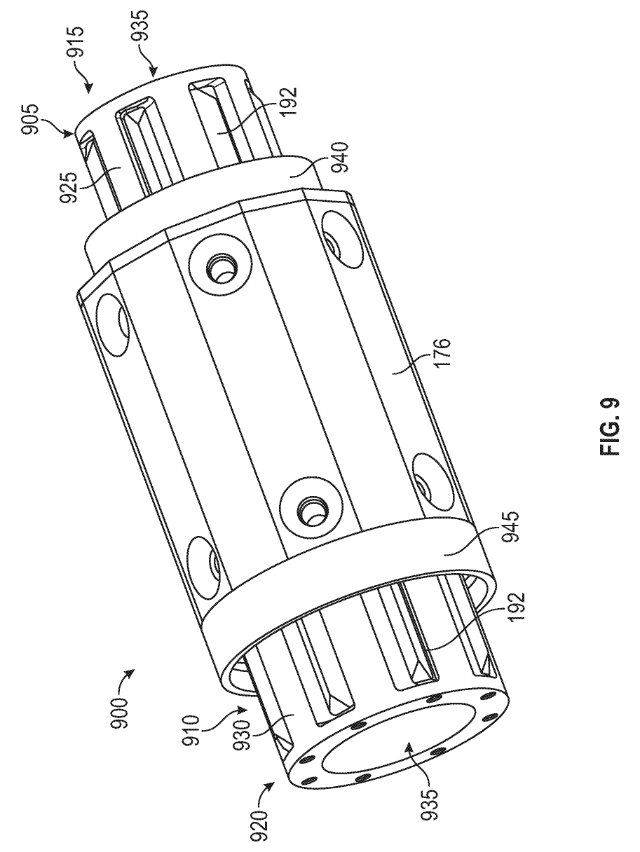

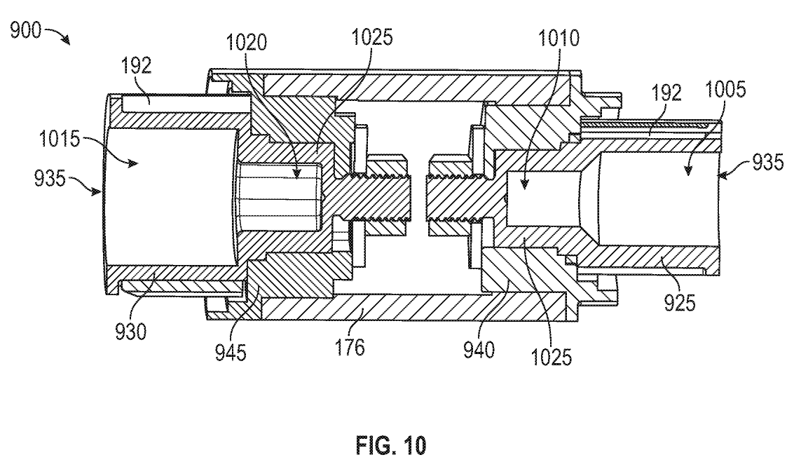

FIGS. 9-12 illustrate another example of a chuck 900. As will be recognized, the chuck 900 shares a number of components in common with and operates in a similar fashion to the examples illustrated and described previously (e.g., the chucks 100, 300, 700). For the sake of brevity, these common features will not be again described below in detail. Rather, previous discussion of commonly named or numbered features, unless otherwise indicated, also applies to example configurations of the chuck 900.

As shown in FIG. 9, the chuck 900 may include a body 176 having a first end 915 and a second end 920. A first support assembly 905 may be arranged at the first end 915 of the body 176, and a second support assembly 910 may be arranged at the second end 920 of the body 176. The first support assembly 905 may include a first support section 925, and the second support assembly 910 may include a second support section 930. Both the first support section 925 and the second support section 930 may include teeth 192 circumferentially arranged around their exterior surfaces. The teeth 192 may be configured to engage an inner surface of a pipe during a threading operation to secure the pipe relative to the chuck 900. A first endcap 940 may be arranged at the first end 915 of the body 176, positioned between the first support assembly 905 and the body 176, to provide a contact surface for the pipe when installed on the first support section. Correspondingly, a second endcap 945 may be arranged at the second end 920 of the body 176, positioned between the second support assembly 910 and the body 176 to provide a contact surface for the pipe when installed on the second support section. In some examples, the first support section 925 and the second support section 930 may have different diameters to accommodate pipes of different sizes. For instance, the first support section 925 may be configured to engage a pipe having a first inner diameter (e.g., 1.5 inches), while the second support section 930 may be configured to engage a pipe having a second, different inner diameter (e.g., 2 inches), allowing the chuck 900 to accommodate multiple pipe sizes without replacement.

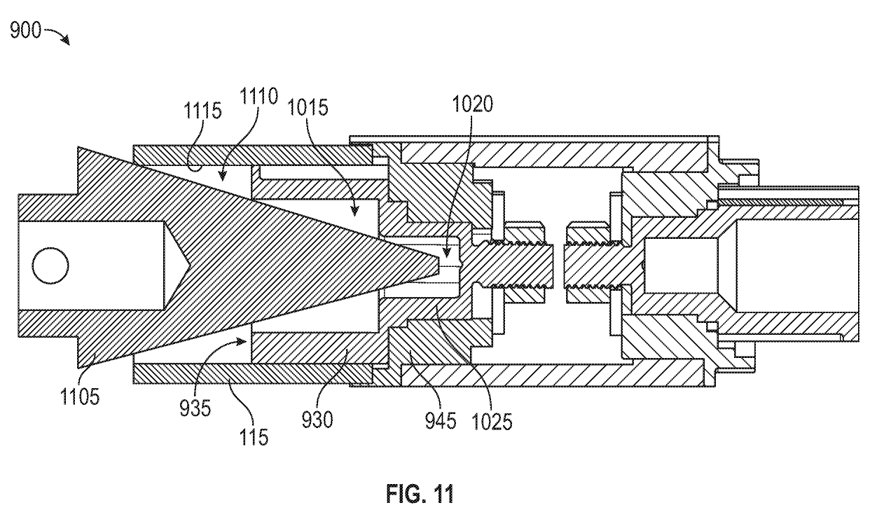

In some examples, the first support section 925 and the second support section 930 may each include openings 935 formed at their distal ends (e.g., at the ends furthest from the body 176). The openings 935 may extend axially through the respective support sections from the distal end toward the body 176. In some examples, the openings 935 may define passages that permit insertion of a reaming cone 1105 (see, e.g., FIG. 11) through the support sections to ream the interior of a pipe (e.g., when the pipe is installed on the support section. This configuration may be particularly useful when manufacturing close nipples, which are short (e.g., less than six inch) pipe nipples with threads on both ends and minimal unthreaded length between them.

In some examples, the chuck 900 may include a first chamber 1005 and a first subchamber 1010 formed within the first support section. The first chamber and the first subchamber may extend from the opening 935 toward the interior of the body 176. Similarly, a second chamber 1015 and a second subchamber 1020 may be formed within the second support section and extend from the opening toward the interior of the body. In some examples, the subchambers may be formed within a stem 1025 of the support sections, which may extend into the endcaps in order to lock the support sections within the body and mitigate rotation of the support section during threading operations.

As mentioned above, the support sections 925, 930 may have open distal ends (e.g., the ends furthest from the body 176) that permit insertion of a reaming cone 1105 into a pipe 115 installed on the support section. The reaming cone 1105 may be used to ream the interior surface 1115 of the pipe 115 to remove burrs, jagged edges, or other irregularities that may result from cutting or threading operations. This open-ended configuration may be particularly beneficial when manufacturing close nipples because the short length of close nipples may otherwise make it difficult to access the pipe interior for reaming (e.g., without contacting the support sections).

As illustrated in FIG. 11, the open-ended configuration of the support sections 925, 930 provides an advantage when reaming close nipples secured on the chuck 900. Specifically, because the support sections 925, 930 include openings 935 at their distal ends that extend axially through the support sections toward the body 176, the reaming cone 1105 can be inserted axially into an interior 1110 of the pipe 115 without interference from the chuck 900. In operation, the reaming cone 1105 may pass through the openings 935 in the respective support section and into the chambers (e.g., the first chamber 1005 or the second chamber 1015) formed within the body 176. This configuration allows the reaming cone 1105 to access and ream the inner surface 1115 of the pipe 115 even when the pipe 115 is a close nipple with minimal unthreaded length. Without the open-ended configuration, the solid structure of support sections would block insertion of the reaming cone 1105, requiring removal of the pipe 115 from the chuck before reaming could be performed. Thus, the open-ended configuration of the chuck 900 enables reaming operations to be performed while the pipe 115 remains secured on the chuck 900, which may improve efficiency and reduce handling time during the manufacturing of close nipples.

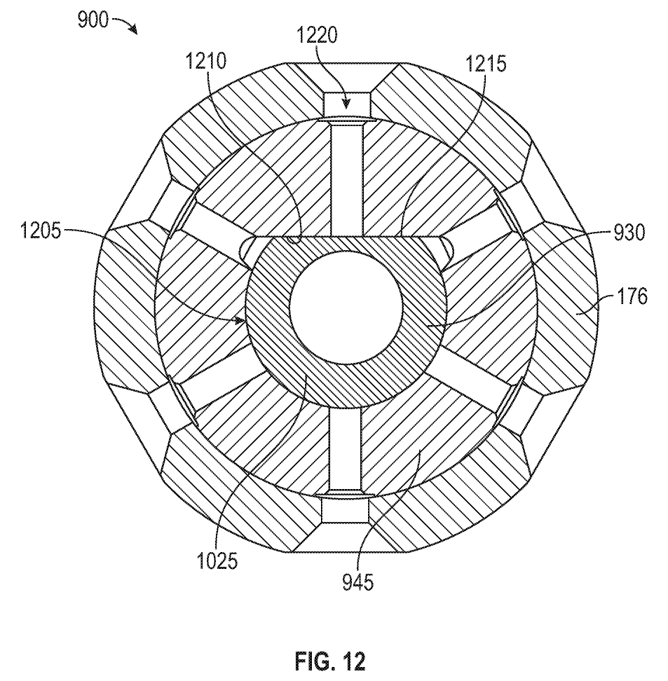

As shown in FIG. 12, the support sections 925, 930 may be secured within the endcaps 940, 945 using a double-D shaped locking mechanism. The double-D shaped locking mechanism may be configured to mitigate rotation of the support sections 925, 930 relative to the body 176 and the endcaps 940, 945 during threading operations. In some examples, the double-D configuration may include complementary flat sections formed on both the stems 1025 of the support sections 925, 930 and corresponding openings 1205 in the endcaps 940, 945. For instance, the stems 1025 may include one or more flat sections 1210 that align and nest within corresponding openings 1205 of the endcaps 940, 945. The openings 1205 may include corresponding flat sections 1215 that mate with the flat sections 1210 of the stems 1025 to create a non-circular cross-sectional profile. This non-circular profile may mitigate relative rotation between the support sections 925, 930 and the endcaps 940, 945 when the components are assembled. Once the stem 1025 is arranged within the opening 1205, one or more fasteners may be arranged through one or more apertures 1220 to further secure the support sections 925, 930 within the endcaps 940, 945 of the body 176. In some examples, the fasteners may extend axially through the support sections and into the body 176 to provide additional structural integrity.

In some implementations, devices or systems disclosed herein can be utilized, manufactured, or installed using methods embodying aspects of the invention. Correspondingly, any description herein of particular features, capabilities, or intended purposes of a device or system is generally intended to include disclosure of a method of using such devices for the intended purposes, a method of otherwise implementing such capabilities, a method of manufacturing relevant components of such a device or system (or the device or system as a whole), and a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as embodiments of the invention, of the utilized features and implemented capabilities of such device or system.

Also as used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “either,” “one of,” “only one of,” or “exactly one of.” For example, a list of “one of A, B, or C” indicates options of: A, but not B and C; B, but not A and C; and C, but not A and B. A list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of A, one or more of B, and one or more of C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C.

As used herein, unless otherwise defined or limited, directional terms are used for convenience of reference for discussion of particular figures or examples. For example, references to downward (or other) directions or top (or other) positions may be used to discuss aspects of a particular example or figure, but do not necessarily require similar orientation or geometry in all installations or configurations.

Also as used herein, unless otherwise limited or defined, “substantially parallel” indicates a direction that is within ± 12 degrees of a reference direction (e.g., within ± 6 degrees), inclusive.

Also as used herein, unless otherwise limited or defined, “substantially perpendicular” indicates a direction that is within ± 12 degrees of perpendicular a reference direction (e.g., within ± 6 degrees), inclusive.

Also as used herein, unless otherwise limited or defined, “integral” and derivatives thereof (e.g., “integrally”) describe elements that are manufactured as a single piece without fasteners, adhesive, or the like to secure separate components together. For example, an element stamped, cast, or otherwise molded as a single-piece component from a single piece of sheet metal or using a single mold, without rivets, screws, or adhesive to hold separately formed pieces together is an integral (and integrally formed) element. In contrast, an element formed from multiple pieces that are separately formed initially then later connected together, is not an integral (or integrally formed) element.

Additionally, unless otherwise specified or limited, the terms “about” and “approximately,” as used herein with respect to a reference value, refer to variations from the reference value of ± 15% or less, inclusive of the endpoints of the range. Similarly, the term “substantially equal” (and the like) as used herein with respect to a reference value refers to variations from the reference value of less than ± 10%, inclusive. Where specified, “substantially” can indicate in particular a variation in one numerical direction relative to a reference value. For example, “substantially less” than a reference value (and the like) indicates a value that is reduced from the reference value by 10% or more, and “substantially more” than a reference value (and the like) indicates a value that is increased from the reference value by 10% or more.

Also as used herein, unless otherwise limited or specified, “substantially identical” refers to two or more components or systems that are manufactured or used according to the same process and specification, with variation between the components or systems that are within the limitations of acceptable tolerances for the relevant process and specification. For example, two components can be considered to be substantially identical if the components are manufactured according to the same standardized manufacturing steps, with the same materials, and within the same acceptable dimensional tolerances (e.g., as specified for a particular process or product).

Unless otherwise specifically indicated, ordinal numbers are used herein for convenience of reference, based generally on the order in which particular components are presented in the relevant part of the disclosure. In this regard, for example, designations such as “first,” “second,” etc., generally indicate only the order in which a thus-labeled component is introduced for discussion and generally do not indicate or require a particular spatial, functional, temporal, or structural primacy or order.

The above detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

It is to be understood that the invention is not limited in its application to the details of construction and the arrangement of components set forth in the above description or illustrated in the drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The previous description of the disclosed embodiments is provided to enable any person skilled in the art to make or use the invention. Given the benefit of this disclosure, various modifications to these embodiments will be readily apparent to those skilled in the art, and the principles defined herein may be applied to other embodiments without departing from the spirit or scope of the invention. Thus, the invention is not intended to be limited to the embodiments shown herein but is to be accorded the widest scope consistent with the principles and novel features disclosed herein.

1. A chuck for a threader tool, comprising:
a body having a first end and a second end;
a first support assembly at the first end of the body, the first support assembly including a first support section with a plurality of teeth circumferentially arranged around the first support section and configured to engage an inner surface of a first pipe of a first diameter;
a second support assembly at the second end of the body, the second support assembly including a second support section with a plurality of teeth circumferentially arranged around the second support section and configured to engage an inner surface of a second pipe of a second, different diameter.

2. The chuck of claim 1, wherein the first support assembly further includes a third support section, and wherein the third support section has a different diameter than the first support section.

3. The chuck of claim 2, wherein the second support assembly further includes a fourth support section, and wherein the fourth support section has a different diameter than the second support section.

4. The chuck of claim 2, further comprising:
a first flange arranged between the first support section and the third support section; and
a second flange arranged between the first support section and the body.

5. The chuck of claim 1, wherein the teeth are configured to:
engage the inner surface of the pipe when the pipe is rotated in a first direction; and
disengage from the inner surface of the pipe when the pipe is rotated in a second direction opposite the first direction.

6. The chuck of claim 1, further comprising:
a biasing element arranged adjacent the plurality of teeth, the biasing element to bias the teeth into contact with an inner surface of a pipe.

7. The chuck of claim 1, wherein each of the plurality of teeth includes a lead-in chamfer configured to guide the pipe along the teeth.

8. The chuck of claim 1, further comprising:
a rotation constraint system, including:
a tab receptacle formed in a first face of the first support section; and
a locking tab extending from a first face of the second support section toward the first face of the first support section, the locking tab engaging with the tab receptacle to prevent rotation of the first and second support sections relative to each other.

9. The chuck of claim 1, wherein the first support section includes an opening formed at a distal end of the first support section, the opening extending axially through the first support section toward the body.

10. The chuck of claim 9, wherein the opening is configured to permit insertion of a reaming cone through the first support section to ream an interior of a pipe installed on the first support section.

11. A method of securing a pipe for a threading operation, the method comprising:
providing a chuck having a body with first and second support assemblies, each of the first and second support assemblies including a support section of a different diameter;
aligning an end of the pipe with the support section corresponding to a diameter of the pipe;
sliding the pipe over the corresponding support section until an end of the pipe contacts a flange extending from the body; and
locking rotation of the chuck and pipe together by rotating the chuck or pipe to cause teeth on the support section to engage an inner surface of the pipe.

12. The method of claim 11, wherein the first support assembly includes:
a first support section; and
a third support section having a different diameter than the first support section.

13. The method of claim 12, wherein the second support assembly includes:
a second support section and
a fourth support section having a different diameter than the second support section.

14. The method of claim 12, further comprising:
a first flange arranged between the first support section and the third support section; and
a second flange arranged between the first support section and the body.

15. The method of claim 11, further comprising:
engaging the teeth with the inner surface of the pipe when the pipe is rotated in a first direction; and
disengaging the teeth from the inner surface of the pipe when the pipe is rotated in a second direction opposite the first direction.

16. A chuck for a threader tool, comprising:
a body having a first end and a second end;
a first support assembly at the first end of the body, the first support assembly including a first support section and a second support section, with the first support section having a larger diameter than the second support section;
a second support assembly at the second end of the body, the second support assembly including a third support section and a fourth support section, with the third support section having a larger diameter than the fourth support section; and
a plurality of spring-loaded teeth circumferentially arranged on each of the support sections, the teeth configured to engage an inner surface of a pipe.

17. The chuck of claim 16, further comprising:
a rotation constraint system, including:
a tab receptacle formed in a first face of the first support section; and
a locking tab extending from a first face of the second support section toward the first face of the first support section, the locking tab engaging with the tab receptacle to prevent rotation of the first and second support sections relative to each other.

18. The chuck of claim 17, wherein the rotation constraint system further includes:
a gusset plate arranged between the first face of the first support section and the first face of the second support section.

19. The chuck of claim 18, wherein the gusset plate includes a thru-hole to permit the locking tab to extend through the gusset plate and into the tab receptacle.

20. The chuck of claim 16, further comprising:
a first flange arranged between the first support section and the second support section; and
a second flange arranged between the first support section and the body.
